(19) United States
(12) Patent Application Publication
(10) Pub. No.: US 2024/0007064 A1
(43) Pub. Date: Jan. 4, 2024

(54) INTEGRATED COMPENSATION OF AMPLITUDE AND PHASE DISTORTIONS

(71) Applicant: SKYWORKS SOLUTIONS, INC., Irvine, CA (US)

(72) Inventor: Philip John LEHTOLA, Cedar Rapids, IA (US)

(21) Appl. No.: 18/141,919

(22) Filed: May 1, 2023

Related U.S. Application Data
(60) Provisional application No. 63/337,162, filed on May 1, 2022.

(51) Int. Cl. H03F 3/24; H03F 1/02

(52) U.S. Cl. CPC H03F 3/245; H03F 1/0222; H03F 2200/451; H03F 2200/462

(57) ABSTRACT

In some embodiments, a power amplifier circuit can include a power amplifier having an input node and an output node, a load modulation circuit coupled to the output node of the power amplifier, and a phase compensation circuit implemented in the input node side of the power amplifier. The power amplifier circuit can further include a control circuit configured to provide a control signal to the load modulation circuit based on a first current representative of a tunable reference current and a second current representative of a saturation detection current. In some embodiments, the control circuit can be further configured to provide a control signal to the phase compensation circuit based on a third current representative of a tunable reference current and the second current.

### CROSS-REFERENCE TO RELATED APPLICATION(S)

This application claims priority to U.S. Provisional Application No. 63/337,162 filed May 1, 2022, entitled INTEGRATED COMPENSATION OF AMPLITUDE AND PHASE DISTORTIONS, the disclosure of which is hereby expressly incorporated by reference herein in its entirety.

### BACKGROUND

### Field

The present disclosure relates to amplifiers for radio-frequency (RF) applications.

### Description of the Related Art

In electronic applications such as radio-frequency (RF) applications, signals can be amplified for a number of reasons. For example, an RF signal to be transmitted can be amplified by a power amplifier, and such an amplified signal can be routed to an antenna for transmission.

### SUMMARY

In accordance with a number of implementations, the present disclosure relates to a power amplifier circuit that includes a power amplifier having an input node and an output node, a load modulation circuit coupled to the output node of the power amplifier, and a phase compensation circuit implemented in the input node side of the power amplifier. The power amplifier circuit further includes a control circuit configured to provide a control signal to the load modulation circuit based on a first current representative of a tunable reference current and a second current representative of a saturation detection current.

In some embodiments, the control circuit can include a translinear multiplier circuit configured to generate the control signal that is proportional to the first current and the second current. In some embodiments, the first current can include an AMAM current.

In some embodiments, the control circuit can be further configured to provide a control signal to the phase compensation circuit based on a third current representative of a tunable reference current and the second current. The control circuit can include a translinear multiplier circuit configured to generate the control signal that is proportional to the third current and the second current. In some embodiments, the third current can include an AMPM current.

In some embodiments, the power amplifier can include an input stage and an output stage. The saturation detection current can be obtained based on detection of saturation at an input of the output stage.

In some embodiments, the phase compensation circuit can be implemented at an input of the input stage. The input stage can be implemented as a driver stage, and the output stage can be implemented as a final stage. The driver stage can be implemented as a cascode driver stage. The cascode driver stage can be configured to operate with a Class AB bias.

In some embodiments, the final stage can be implemented as a push-pull amplifier. The push-pull amplifier can include a splitter having an input and a pair of outputs, with each output being coupled to an input of a respective amplifier, and the push-pull amplifier further including a combining circuit that combines outputs of the pair of amplifiers. Each of the pair of amplifiers can be configured to operate with a Class AB bias. The combining circuit can include a transformer circuit having a primary with first and second nodes coupled to the outputs of the pair of amplifiers, and a secondary with first and second nodes, with the first node being coupled to an output node and the second node being coupled to ground through the load modulator.

In some implementations, the present disclosure relates to a method for amplifying a radio-frequency signal. The method includes receiving a signal at an input node, providing a phase shift for the signal with a phase shifting circuit, amplifying the phase shifted signal, and providing load modulation for the amplified signal by providing a control voltage that is based on a first current representative of a tunable reference current and a second current representative of a saturation detection current.

In some embodiments, the first current can include an AMAM current.

In some embodiments, the phase shift can be provided by a control signal from the control circuit based on a third current representative of a tunable reference current and the second current. The third current can include an AMPM current.

In some implementations, the present disclosure relates to a semiconductor die that includes a substrate and a power amplifier circuit implemented on the substrate. The power amplifier circuit includes a power amplifier having an input node and an output node, a load modulation circuit coupled to the output node of the power amplifier, and a phase compensation circuit implemented in the input node side of the power amplifier. The power amplifier circuit further includes a control circuit configured to provide a control signal to the load modulation circuit based on a first current representative of a tunable reference current and a second current representative of a saturation detection current.

In some embodiments, the control circuit can be further configured to provide a control signal to the phase compensation circuit based on a third current representative of a tunable reference current and the second current.

In some embodiments, the substrate can be configured to support heterojunction bipolar transistors.

In some implementations, the present disclosure relates to a packaged module that includes a packaging substrate and a power amplifier circuit implemented on the packaging substrate. The power amplifier circuit includes a power amplifier having an input node and an output node, a load modulation circuit coupled to the output node of the power amplifier, and a phase compensation circuit implemented in the input node side of the power amplifier. The power amplifier circuit further includes a control circuit configured to provide a control signal to the load modulation circuit based on a first current representative of a tunable reference current and a second current representative of a saturation detection current.

In some embodiments, the control circuit can be further configured to provide a control signal to the phase compensation circuit based on a third current representative of a tunable reference current and the second current.

In some embodiments, the power amplifier circuit can be implemented on a single semiconductor die.

In some embodiments, the packaged module can be implemented as a power amplifier module.

In some implementations, the present disclosure relates to a wireless device that includes an antenna and an amplifier circuit configured to amplify a radio-frequency signal associated with the antenna. The amplifier circuit includes an amplifier, a load modulation circuit coupled to an output of the amplifier, and a phase compensation circuit implemented on an input side of the amplifier. The amplifier circuit further includes a control circuit configured to provide a control signal to the load modulation circuit based on a first current representative of a tunable reference current and a second current representative of a saturation detection current.

In some embodiments, the control circuit can be further configured to provide a control signal to the phase compensation circuit based on a third current representative of a tunable reference current and the second current.

In some embodiments, the amplifier circuit can be implemented as a power amplifier circuit. The antenna can be configured to support a transmit operation of the amplified radio-frequency signal provided by the power amplifier.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows that in some embodiments, a power amplifier system can include a load modulation circuit, a phase compensation circuit implemented on the input side of the power amplifier, and a control circuit configured to control the load modulator and the phase compensation circuit.

FIG. 2 shows an example of a control circuit that can be implemented to generate a control voltage for controlling the load modulator of FIG. 1.

FIG. 3A shows the control circuit of FIG. 2 with control voltages VCTRL_AMAM and VB2 emphasized.

FIG. 3B shows plots of VCTRL_AMAM as a function of VB2 when a current IAMAM is swept through a range.

FIG. 4A shows the control circuit of FIG. 2 with the control voltage VCTRL_AMAM and a current ISAT_DET emphasized.

FIG. 4B shows plots of IMULT_OUT, VB_EF and VCTRL_AMAM as a function of ISAT_DET for different temperatures.

FIG. 5A shows the control circuit of FIG. 2 with parameters IAMAM, AMAM CTRL and ISAT_DET emphasized.

FIG. 5B shows plots of VCTRL_AMAM response without load modulation and VCTRL_AMAM response with load modulation for different temperatures.

FIG. 6A shows the control circuit of FIG. 2 with a loop portion emphasized.

FIG. 6B shows loop gain, loop phase and phase margin plots for different temperatures.

FIG. 7 shows plots of gain of the power amplifier of FIG. 1 as a function of output power as the current IAMAM of the control circuit of FIG. 2 is swept.

FIG. 8 shows plots of CW AMAM as a function of output power as the current IAMAM is swept, and plots of PAE as a function of output power as the current IAMAM is swept.

FIG. 9 shows plots of CW IBIAS current as a function of output power as the current IAMAM is swept.

FIG. 10 shows plots of 4*SQRT(ISAT_DET*IAMAM)+ISAT_DET as a function of output power as the current IAMAM is swept.

FIG. 11 shows plots of phase as a function of output power as the current IAMPM is swept.

FIG. 12 shows representative plots of phase as a function output power, with and without phase compensation based on the current IAMPM.

FIG. 13 shows that in some embodiments, a semiconductor die can include a control circuit as described herein.

FIG. 14 shows that in some embodiments, one or more features as described herein can be implemented in a packaged module.

FIG. 15 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

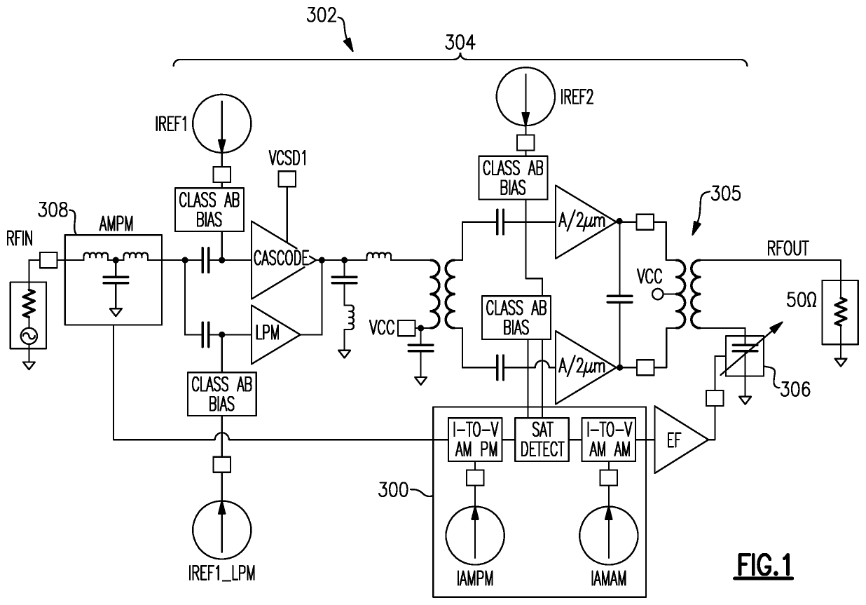

FIG. 1 shows a power amplifier system 302 configured to receive a signal as an input (RF_IN) and amplify the signal with a power amplifier 304. The amplified signal can then be provided as an output (RF_OUT). As described herein, the power amplifier system 302 may also be referred to as a power amplifier circuit, or simply as a power amplifier.

Although various examples are described herein in the context of power amplifiers, it will be understood that in some embodiments, one or more features of the present disclosure can also be utilized for other types of amplifiers.

FIG. 1 shows that in some embodiments, the power amplifier system 302 can include a load modulation (LM) circuit 306. Such a load modulation circuit (also referred to herein as a load modulator) can be coupled to an output side of the power amplifier 304.

In some embodiments, the load modulator 306 can be configured to provide variable capacitance that is controlled by a control voltage.

FIG. 1 shows that in some embodiments, the power amplifier system 302 can also include a phase compensation circuit 308 implemented on the input side of the power amplifier 304. For example, the phase compensation circuit 308 can be implemented between the input RF_IN and a DC-blocking capacitance on the input side of the power amplifier 304.

In some embodiments, the phase compensation circuit 308 can be configured to provide variable capacitance that is controlled by a control voltage.

Referring to FIG. 1, the power amplifier system 302 can include a control circuit 300 configured to control the load modulator 306 and the phase compensation circuit 308. In some embodiments, the control circuit 300 can be utilized for operation of either or both of the load modulator 306 and the phase compensation circuit 308.

In the example of FIG. 1, the power amplifier 304 is implemented as a power amplifier having a push-pull architecture. Such an architecture is shown to include a cascode driver stage and an inverse F push-pull final stage. In such an architecture, the load modulator 306 can be coupled to a secondary of an output combining/matching balun circuit 305 combines the outputs of two amplifiers (each indicated as A/2) of the push-pull final stage.

In the example of FIG. 1, each of the cascode driver stage and the push-pull final stage is depicted as being provided with Class AB bias. However, it will be understood that one or more features of the present disclosure can also be implemented in power amplifiers having different bias configurations.

FIG. 1 shows that in some embodiments, the control circuit 300 can be configured to generate a control voltage for the load modulator 306 based on a current IAMAM and saturation detection, and a control voltage for the phase compensation circuit 308 based on a current IAMPM and the saturation detection. Additional details and examples of such generation of control voltages based on respective currents and the saturation detection are described herein.

In the example of FIG. 1, the driver stage that includes the cascode amplifier is also shown to include a low-power mode (LPM) amplifier in parallel with the cascode amplifier. Such a low-power mode amplifier can be enabled (and the cascode amplifier disabled) when the input power is below some level. It will be understood that a power amplifier having one or more features as described herein may or may not include such a low-power mode amplifier.

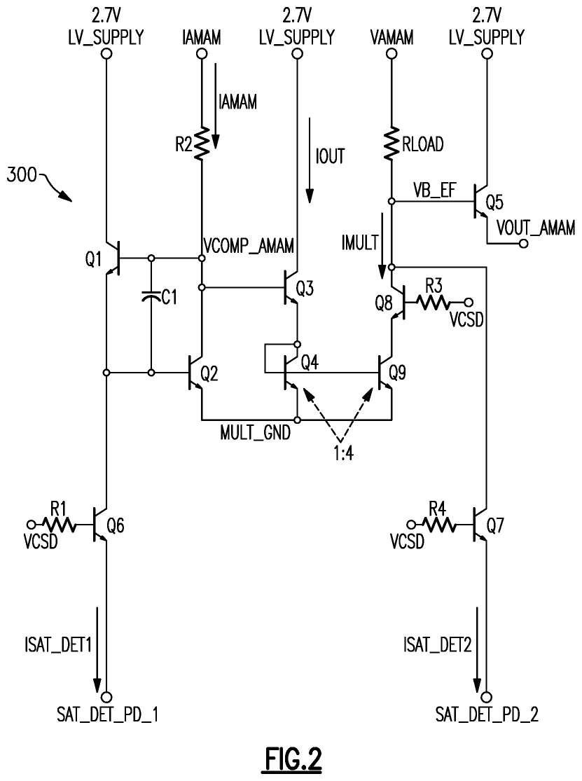

FIG. 2 shows an example of a control circuit 300 that can be implemented to generate a control voltage for controlling the load modulator 306 of FIG. 1. In FIG. 2, a voltage node LV_SUPPLY (e.g., 2.7V) is shown to be coupled to a saturation detector node SAT_DET_PD_1 through transistors Q1 and Q6, such that the collector of Q1 is coupled to LV_SUPPLY, the emitter of Q1 is coupled to the collector of Q6, and the emitter of Q6 is coupled to SAT_DET_PD_1. The base of Q1 is shown to be coupled to the emitter of Q1 through a capacitance C1, and the base of Q6 is shown to be coupled to an enable signal node VCSD through a resistance R1.

Referring to FIG. 2, the base of Q1 is also shown to be coupled to a current node IAMAM through a resistance R2, so as to provide a voltage VCOMP_AMAM. The current node IAMAM is coupled to a ground node MULT_GND through the foregoing R2 and a transistor Q2, such that the collector of Q2 is coupled to R2 and the emitter of Q2 is coupled to the ground (MULT_GND). The base of Q2 is coupled to the emitter of Q1 (and thus to the collector of Q6).

Referring to FIG. 2, the voltage node LV_SUPPLY (e.g., 2.7V) is also shown to be coupled to the ground (MULT_GND) through transistors Q3 and Q4, such that the collector of Q3 is coupled to LV_SUPPLY, the emitter of Q3 is coupled to the collector of Q4, and the emitter of Q4 is coupled to the ground (MULT_GND). The base of Q3 is shown to be coupled to the node VCOMP_AMAM between R2 and Q2.

Referring to FIG. 2, a voltage node VAMAM is shown to be coupled to the ground (MULT_GND) through a resistance RLOAD and transistors Q8 and Q9, such that the collector of Q8 is coupled to RLOAD, the emitter of Q8 is coupled to the collector of Q9, and the emitter of Q9 is coupled to the ground (MULT_GND). The base of Q8 is shown to be coupled to the enable signal node VCSD through a resistance R3. The base of Q9 is shown to be coupled to the base of Q4 (and thus to the node between Q3 and Q4). A node between RLOAD and Q8 is shown to be provided with a voltage VB_EF.

Referring to FIG. 2, the voltage node LV_SUPPLY (e.g., 2.7V) is also shown to be coupled to a control voltage output node VOUT_AMAM through a transistor Q5, such that the collector of Q5 is coupled to LV_SUPPLY, and the emitter of Q5 is coupled to VOUT_AMAM. The base of Q5 is shown to be coupled to the node VB_EF between RLOAD and Q8.

Referring to FIG. 2, the foregoing node VB_EF between RLOAD and Q8 is also shown to be coupled to an optional saturation detector node SAT_DET_PD_2 through a transistor Q7, such that the collector of Q7 is coupled to VB_EF and the emitter of Q7 is coupled to SAT_DET_PD_2. The base of Q7 is shown to be coupled to the enable signal node VCSD through a resistance R4.

Configured in the foregoing manner, a control voltage VOUT_AMAM can be generated based on a current IAMAM and a current ISAT_DET1 representative of saturation detection in the push-pull final stage of the power amplifier 304 of FIG. 1. Accordingly, the control circuit 300 of FIG. 2 can represent or be associated with functional blocks “Sat Detect” and “I-to-V AMAM” in the control circuit 300 of FIG. 1.

Referring to FIGS. 1 and 2, it is noted that the transistors Q6 and Q7 can utilize VCSD as an enable signal. It is also noted that the current ISAT_DET2 may or may not be utilized for the control voltage VOUT for AMAM tuning.

In the example of FIG. 2, one can see that V_{BE1}+V_{BE2}=V_{BE3}+V_{BE4}. Thus, V_{T} In(ISAT_DET1)+V_{T} In(IAMAM)=V_{T} In(IOUT)+V_{T} In(IOUT). Further, ISAT_DET1*IAMAM=IOUT². Thus, IOUT=sqrt(ISAT_DET1*IAMAM). Accordingly, VOUT=VAMAM−RLOAD*(4*sqrt(ISAT_DET1*IAMAM)+ISAT_DET2))−VBE5.

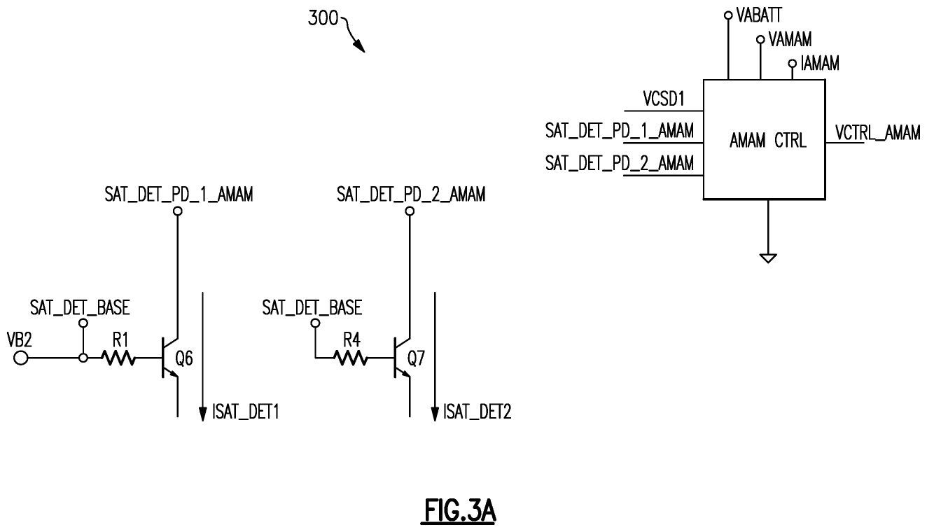

FIG. 3A shows the control circuit 300 of FIG. 2 with the control voltage VCTRL_AMAM and VB2 emphasized. It is noted that VCTRL_AMAM is representative of the control voltage of FIG. 2 for controlling the load modulator (306 in FIG. 1), and VB2 is representative of VCSD for enabling the transistors Q6 and Q7 of FIG. 2.

FIG. 3B shows plots of VCTRL_AMAM as a function of VB2 when the current IAMAM is swept through a range. A desired relationship between VCTRL_AMAM and VB2, indicated as shown, can be obtained based on such plots.

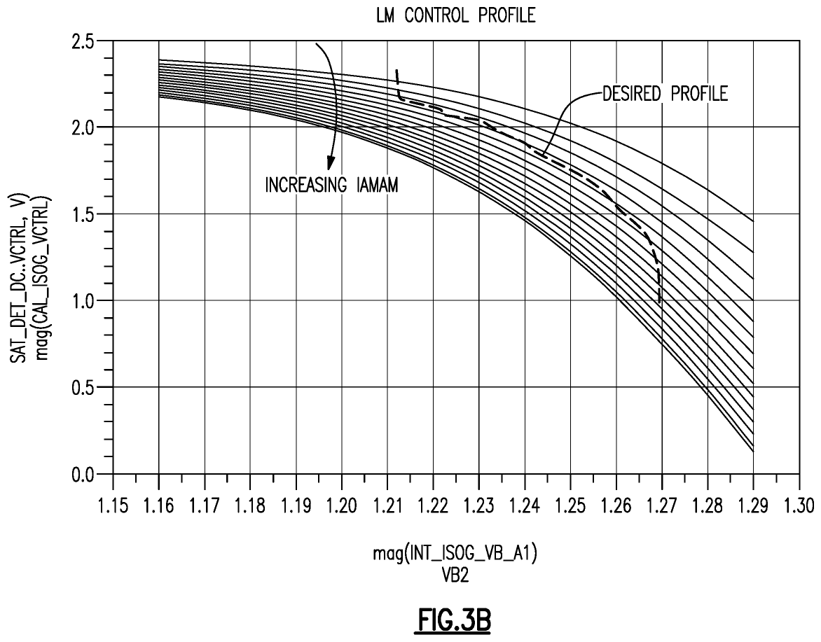

FIG. 4A shows the control circuit 300 of FIG. 2 with the control voltage VCTRL_AMAM and the current ISAT_DET emphasized. FIG. 4B shows plots of IMULT_OUT (top panel), VB_EF (middle panel) and VCTRL_AMAM (bottom pane) as a function of ISAT_DET for different temperatures in a range of −30 deg. C to 85 deg. C. As shown in the top panel, the output current is very consistent over the temperature range.

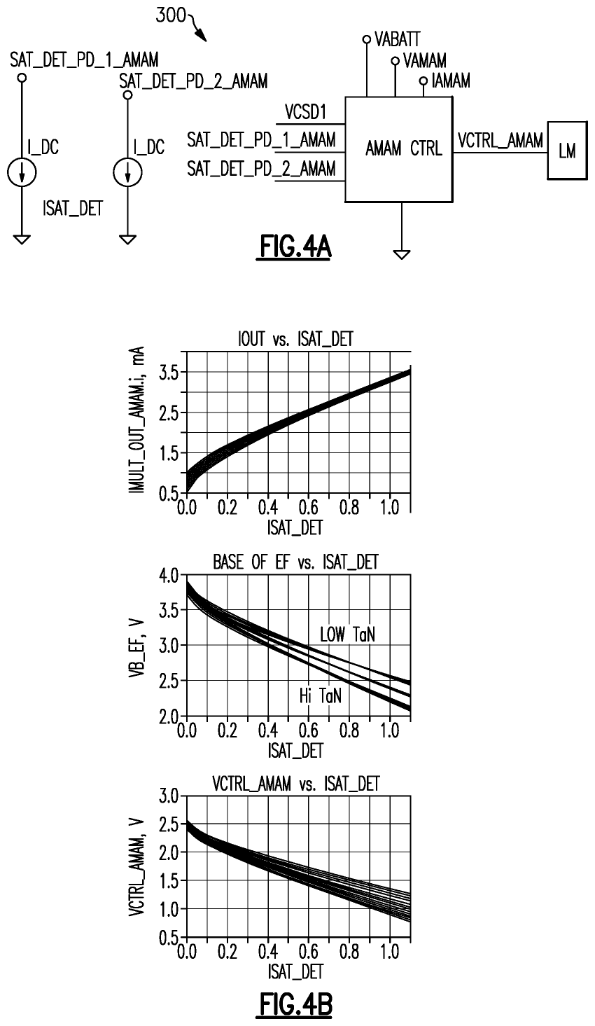

FIG. 5A shows the control circuit 300 of FIG. 2 with the parameters IAMAM, AMAM CTRL and ISAT_DET emphasized. FIG. 5B shows plots of VCTRL_AMAM response without load modulation (top panel) and VCTRL_AMAM response with load modulation (bottom panel) for different temperatures in a range of −30 deg. C to 85 deg. C.

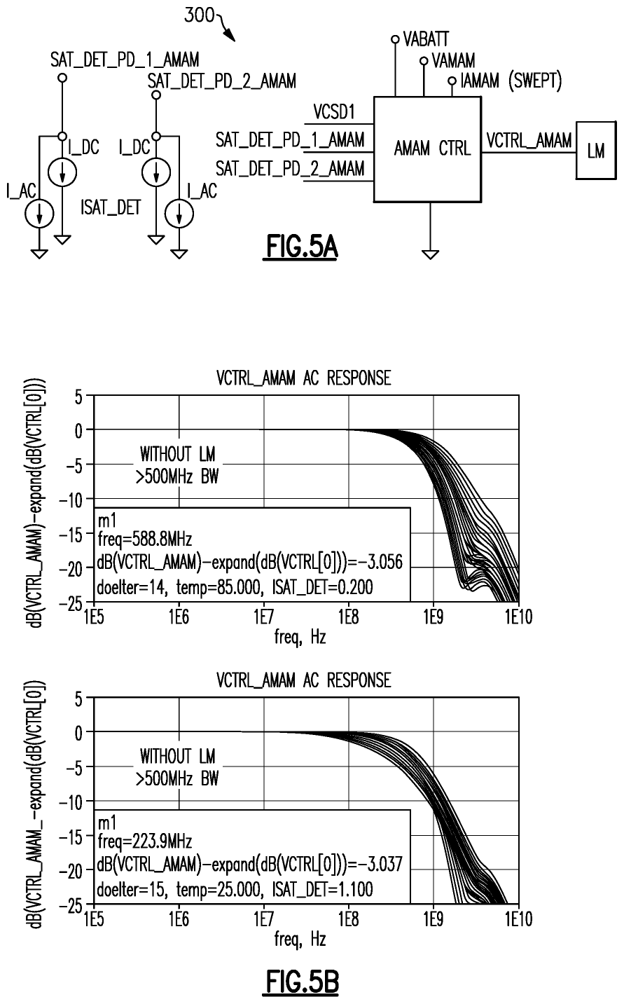

FIG. 6A shows the control circuit 300 of FIG. 2 with a loop portion emphasized. FIG. 6B shows loop gain, loop phase and phase margin plots for different temperatures in a range of −30 deg. C to 85 deg. C. As shown in the bottom panel, a minimum phase margin of 58.5 degrees is present.

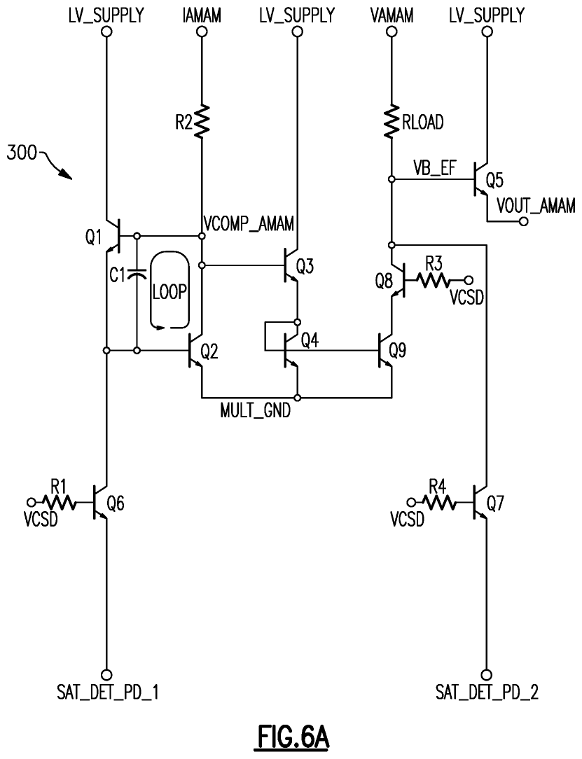

FIGS. 7 to 10 show various plots obtained from measurements associated with the control circuit 300 of FIG. 2.

FIG. 7 shows plots of gain of the power amplifier 304 of FIG. 1 as a function of output power as the current IAMAM of the control circuit 300 of FIG. 2 is swept. The uppermost curve corresponds to the operating mode where the load modulation control is off and load modulation of always on.

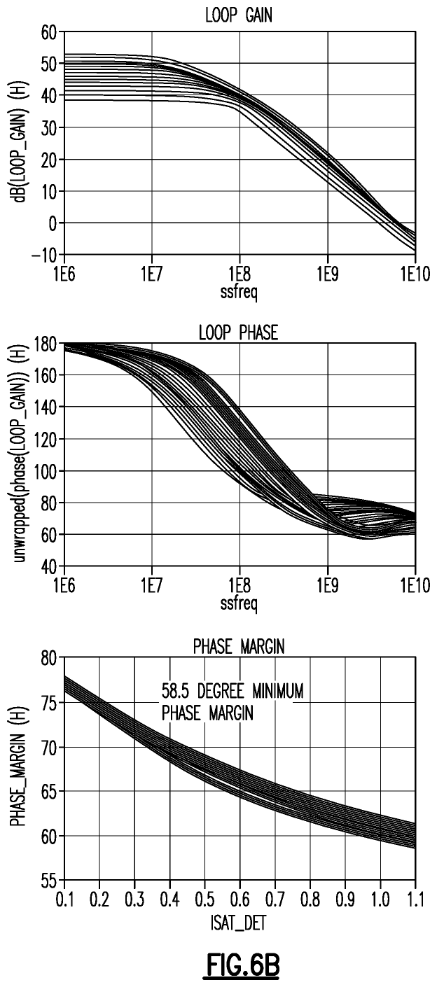

FIG. 8 shows plots of CW AMAM as a function of output power as the current IAMAM is swept. FIG. 8 also shows plots of PAE as a function of output power as the current IAMAM is swept.

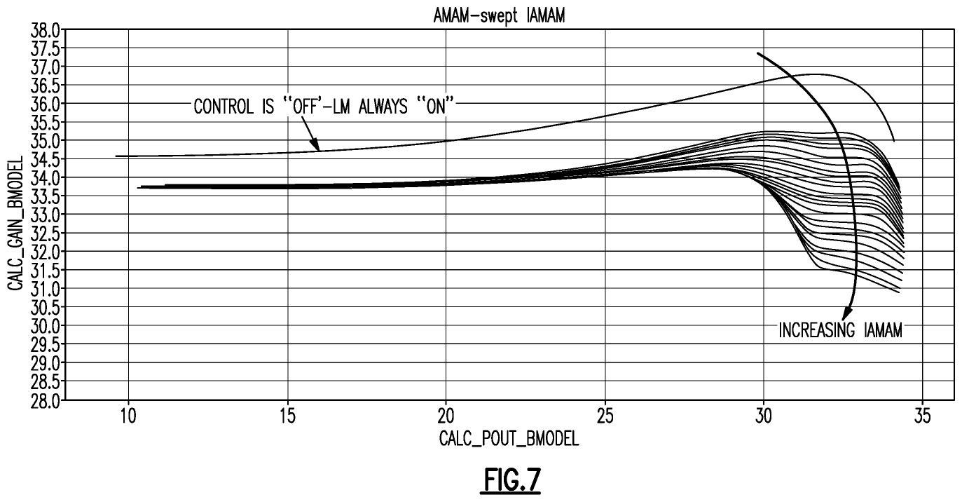

FIG. 9 shows plots of CW IBIAS current (load modulator current plus PA bias current) as a function of output power as the current IAMAM is swept. One can see that the load modulator displays an abrupt turn on after 30 dBM in output power with an optimized bias.

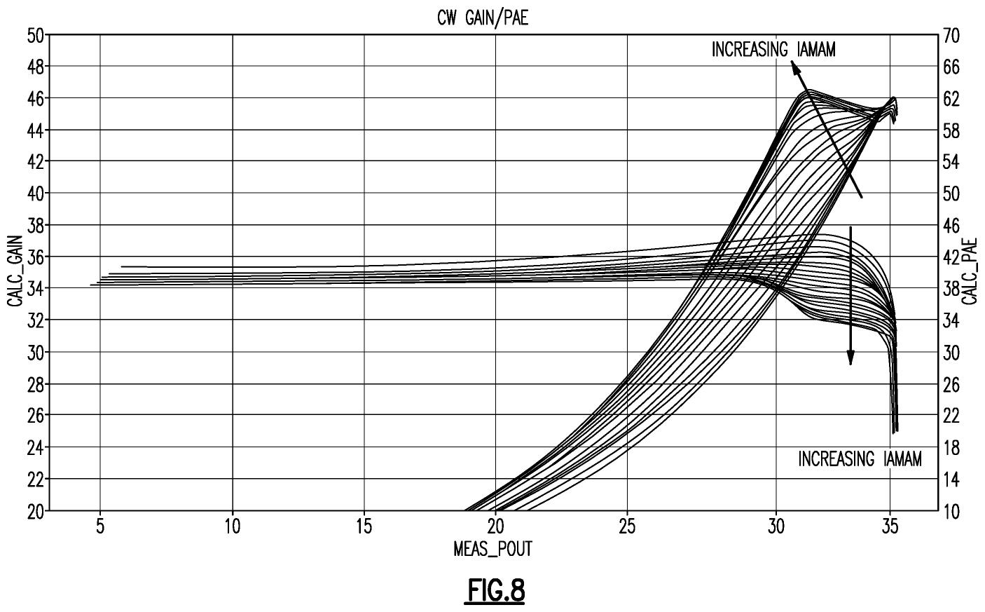

FIG. 10 shows plots of 4*SQRT(ISAT_DET*IAMAM)+ISAT_DET as a function of output power as the current IAMAM is swept. One can see that the saturation detection current ISAT_DET decreases as the output stage compresses.

FIGS. 2 to 10 are related to control of the load modulator 306 of FIG. 1. As described herein, similar control functionality can be provided by, or similar to, the control circuit 300 of FIG. 2, by utilizing current IAMPM instead of IAMAM. In some embodiments, such a current (IAMPM) can be an external reference current, and the control circuit 300 of FIG. 2 can utilize such a reference current to control the phase compensation circuit 308 of FIG. 1.

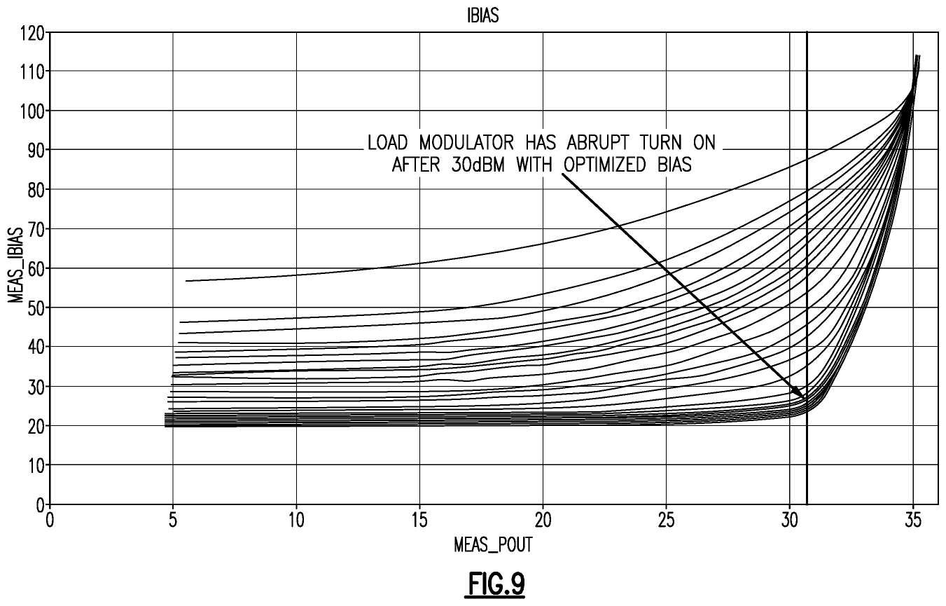

For example, FIG. 11 shows plots of phase as a function of output power as the current IAMPM is swept.

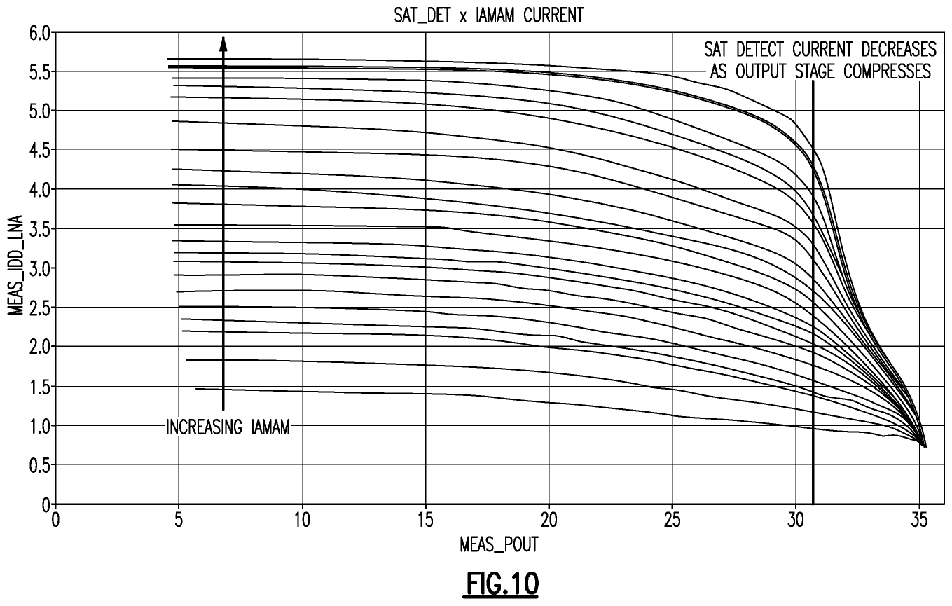

FIG. 12 shows representative plots of phase as a function output power, with and without phase compensation based on the current IAMPM. In the example of FIG. 12, approximately 10 degrees of phase compensation is being provided by the phase compensation circuit.

As described herein, phase compensation can be implemented as analog circuitry configured to support adjustable threshold, gain and shaping to interface between peak detect/saturation detection and load/phase modulator circuits. As also described herein such phase compensation can process a saturation detection output current with a trans-linear multiplier circuit. The output of such a circuit can be proportional to the saturation detection current and a tunable current source.

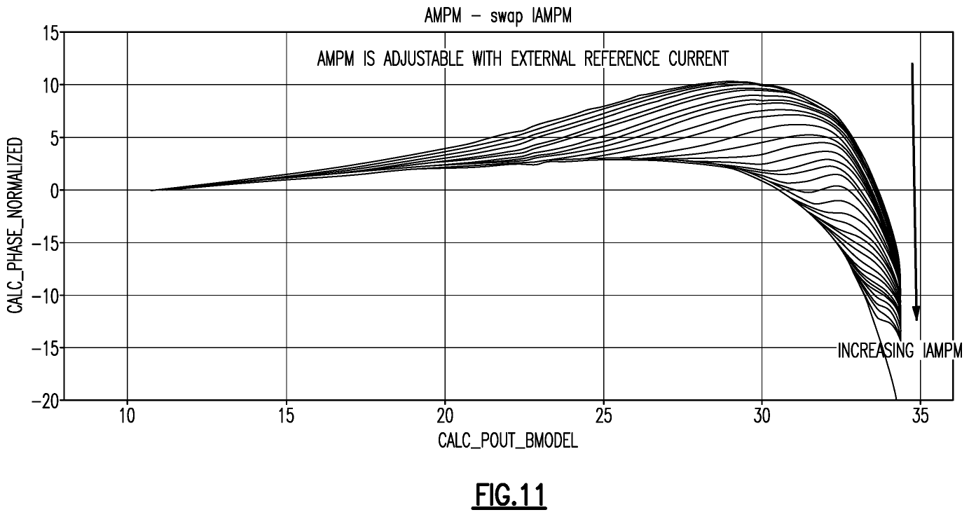

FIG. 13 shows that in some embodiments, a semiconductor die 700 can include a control circuit 300 as described herein. Such a control circuit can be implemented on a semiconductor substrate 702. In some embodiments, the die 700 can further include a power amplifier and either or both of load modulator and phase compensation circuit as described herein.

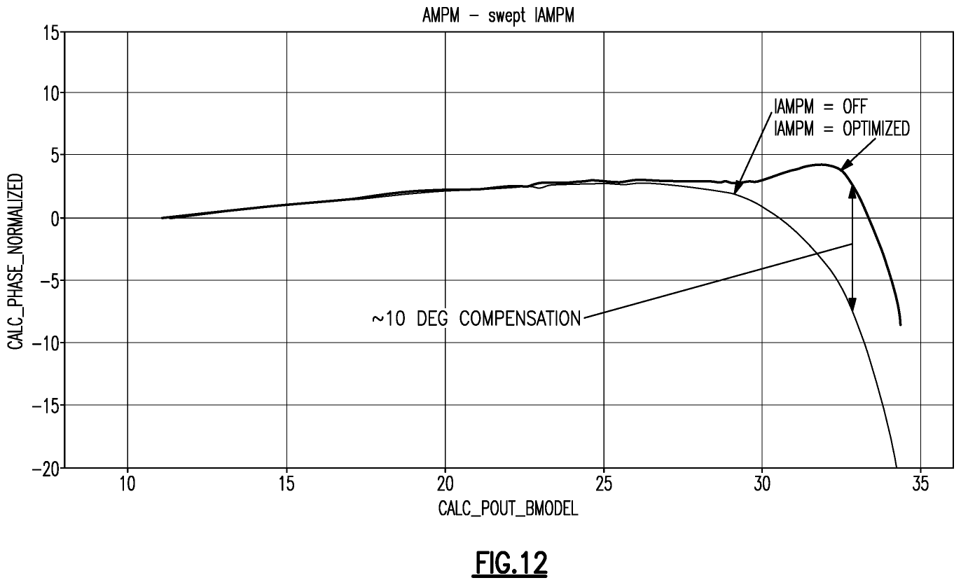

FIG. 14 shows that in some embodiments, one or more features as described herein can be implemented in a packaged module 800. Such a packaged module can include a packaging substrate 802 configured to receive a plurality of components. At least some of the components mounted on the packaging substrate 802 can include a die such as the die 700 of FIG. 13.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

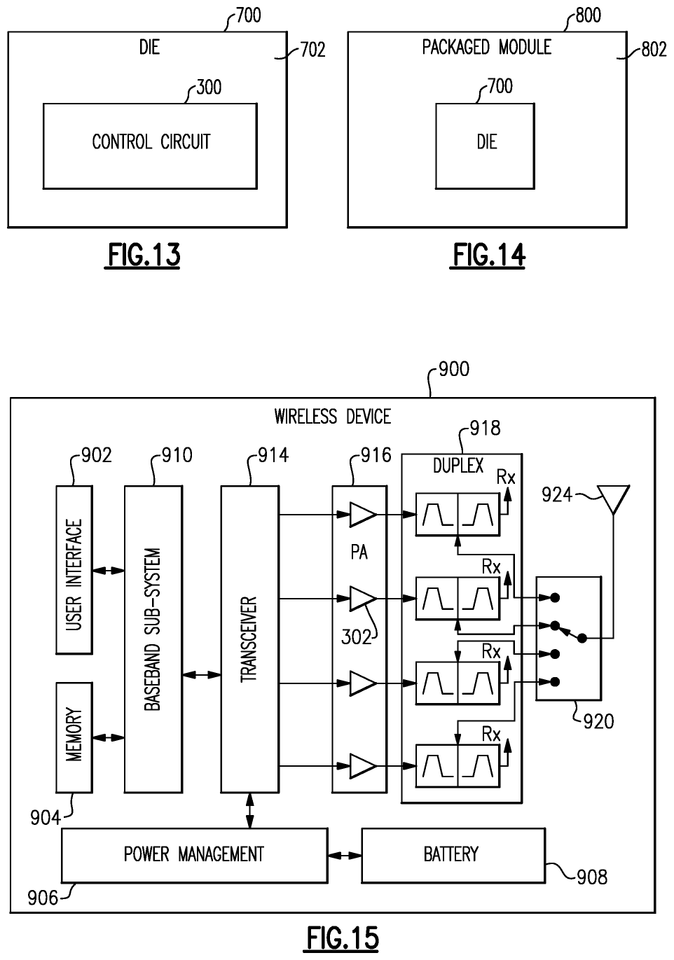

FIG. 15 depicts an example wireless device 900 having one or more advantageous features described herein. In some embodiments, one or more power amplifiers 302 can include a control circuit as described herein. In some embodiments, such one or more power amplifiers can be implemented on a power amplifier module 916.

In the example wireless device 900, the power amplifier (PA) module 916 having a plurality of PAs can provide one or more amplified RF signals to the switch 920 (via an assembly of one or more duplexers 918), and the switch 920 can route the amplified RF signal(s) to one or more antennas. In some embodiments, the PAs in the module 916 can receive corresponding unamplified RF signal(s) from a transceiver 914 that can be configured and operated in known manners. The transceiver 914 can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900.

The baseband sub-system 910 is shown to be connected to a user interface 902 to facilitate various input and output of voice and/or data provided to and received from the user. The baseband sub-system 910 can also be connected to a memory 904 that is configured to store data and/or instructions to facilitate the operation of the wireless device, and/or to provide storage of information for the user.

In some embodiments, the duplexers 918 can allow transmit and receive operations to be performed simultaneously using a common antenna (e.g., 924). In FIG. 15, received signals are shown to be routed to “Rx” paths that can include, for example, one or more low-noise amplifiers (LNAs).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A power amplifier circuit comprising:
a power amplifier having an input node and an output node;
a load modulation circuit coupled to the output node of the power amplifier;
a phase compensation circuit implemented in the input node side of the power amplifier; and
a control circuit configured to provide a control signal to the load modulation circuit based on a first current representative of a tunable reference current and a second current representative of a saturation detection current.

2. The power amplifier circuit of claim 1 wherein the control circuit includes a translinear multiplier circuit configured to generate the control signal that is proportional to the first current and the second current.

3. The power amplifier circuit of claim 2 wherein the first current includes an AMAM current.

4. The power amplifier circuit of claim 1 wherein the control circuit is further configured to provide a control signal to the phase compensation circuit based on a third current representative of a tunable reference current and the second current.

5. The power amplifier circuit of claim 4 wherein the control circuit includes a translinear multiplier circuit configured to generate the control signal that is proportional to the third current and the second current.

6. The power amplifier circuit of claim 2 wherein the third current includes an AMPM current.

7. The power amplifier circuit of claim 1 wherein the power amplifier includes an input stage and an output stage.

8. The power amplifier circuit of claim 3 wherein the saturation detection current is obtained based on detection of saturation at an input of the output stage.

9. The power amplifier circuit of claim 3 wherein the phase compensation circuit is implemented at an input of the input stage.

10. The power amplifier of claim 5 wherein the input stage is implemented as a driver stage, and the output stage is implemented as a final stage.

11. The power amplifier circuit of claim 6 wherein the driver stage is implemented as a cascode driver stage.

12. The power amplifier of claim 7 wherein the cascode driver stage is configured to operate with a Class AB bias.

13. The power amplifier circuit of claim 3 wherein the final stage is implemented as a push-pull amplifier.

14. The power amplifier of claim 9 wherein the push-pull amplifier includes a splitter having an input and a pair of outputs, each output coupled to an input of a respective amplifier, the push-pull amplifier further including a combining circuit that combines outputs of the pair of amplifiers.

15. The power amplifier of claim 10 wherein each of the pair of amplifiers is configured to operate with a Class AB bias.

16. The power amplifier of claim 10 wherein the combining circuit includes a transformer circuit having a primary with first and second nodes coupled to the outputs of the pair of amplifiers, and a secondary with first and second nodes, the first node coupled to an output node and the second node coupled to ground through the load modulator.

17. A method for amplifying a radio-frequency signal, the method comprising:
receiving a signal at an input node;
providing a phase shift for the signal with a phase shifting circuit;
amplifying the phase shifted signal; and
providing load modulation for the amplified signal by providing a control voltage that is based on a first current representative of a tunable reference current and a second current representative of a saturation detection current.

18. The method of claim 17 wherein the first current includes an AMAM current.

19. The method of claim 17 wherein the phase shift is provided by a control signal from the control circuit based on a third current representative of a tunable reference current and the second current.

20. (canceled)

21. (canceled)

22. (canceled)

23. (canceled)

24. (canceled)

25. (canceled)

26. (canceled)

27. (canceled)

28. A wireless device comprising:
an antenna; and
an amplifier circuit configured to amplify a radio-frequency signal associated with the antenna, the amplifier circuit including an amplifier, a load modulation circuit coupled to an output of the amplifier, and a phase compensation circuit implemented on an input side of the amplifier, the amplifier circuit further including a control circuit configured to provide a control signal to the load modulation circuit based on a first current representative of a tunable reference current and a second current representative of a saturation detection current.

29. (canceled)

30. (canceled)

31. (canceled)
